(19) United States
(12) Patent Application Publication
(10) Pub. No.: US 2025/0006494 A1
(43) Pub. Date: Jan. 2, 2025

(54) PATTERNING METHODS, SEMICONDUCTOR STRUCTURES AND MEMORY

(71) Applicant: Yangtze Memory Technologies Co., Ltd., Wuhan, Hubei (CN)

(72) Inventors: Zijin Yang, Wuhan, (CN); Ya Wang, Wuhan (CN); Wenxiang Xu, Wuhan (CN); FanDong Liu, Wuhan (CN); WenYu Hua, Wuhan, (CN)

(21) Appl. No.: 18/625,916

(22) Filed: Apr. 3, 2024

(30) Foreign Application Priority Data
Jun. 28, 2023 (CN) 202310785990.3

(51) Int. Cl. H01L 21/027; H01L 21/308; H01L 21/311

(52) U.S. Cl. CPC H01L 21/0273; H01L 21/3086; H01L 21/31144

(57) ABSTRACT

The present application discloses a patterning method, a semiconductor structure and a memory. The patterning method includes: after forming a mandrel structure in a mask layer on a side of a to-be-etched layer, removing part of the mandrel structure to form a first trench with a smaller length and a second trench with a larger length, and forming a first mask pattern and a second mask pattern through the first trench and the second trench so as to form a first patterned structure and a second patterned structure of different lengths. The present application can improve the applicability of the patterning method, and reduce the process difficulty and cost of fine patterning for forming patterns of different sizes, such that the patterning method provided by the present application can meet more process requirements.

### CROSS REFERENCE TO RELATED APPLICATION

This application claims priority to and the benefit of Chinese Patent Application 202310785990.3, filed on Jun. 28, 2023, which is hereby incorporated by reference in its entirety.

### TECHNICAL FIELD

The present application relates to the field of semiconductor technologies, and particularly to a patterning method, a semiconductor structure and a memory.

### BACKGROUND

The Self Aligned Doubled Patterning (SADP) technology and Reverse Self Aligned Doubled Patterning (Reverse SARP) technology are mainstream technologies currently used for fabricating a dense array pattern.

Through the above process procedures, a pattern with a target pitch can be fabricated, and has a multiplied pattern density compared with a pattern (i.e., a mandrel structure) defined by a first-time patterning fabrication process.

### BRIEF DESCRIPTION OF THE DRAWINGS

The technical solution and other advantageous effects of the present application will become apparent through the detailed description of specific examples of the present application below in conjunction with the drawings.

FIGS. 1 to 7 are schematic structural diagrams of a fabrication process of a patterning method provided by some examples;

FIG. 8 is a flow diagram of a patterning method provided by some examples of the present application;

FIGS. 9, 11, 13, 15, 17, 19, 21, 23, 25, 27 and 29 are multiple top views in a fabrication process corresponding to a patterning method as shown in FIG. 8 provided by some examples of the present application;

FIGS. 10, 12, 14, 16, 18, 20, 22, 24, 26, 28 and 30 are multiple front views in a fabrication process corresponding to a patterning method as shown in FIG. 8 provided by some examples of the present application;

FIGS. 31, 33, 35, 37, 39, 41, 43, and 45 are multiple top views in another fabrication process corresponding to a patterning method as shown in FIG. 8 provided by some examples of the present application;

FIGS. 32, 34, 36, 38, 40, 42, 44, and 46 are multiple front views in another fabrication process corresponding to a patterning method as shown in FIG. 8 provided by some examples of the present application;

FIG. 47 is a schematic structural diagram of a first patterned structure and a second patterned structure provided by some examples of the present application;

FIG. 48 is another schematic structural diagram of a first patterned structure and a second patterned structure provided by some examples of the present application; and

FIG. 49 is schematic structural diagram of a memory system provided by some examples of the present application.

### DETAILED DESCRIPTION

The technical solutions in examples of the present application will be described below clearly and completely in conjunction with the drawings in the examples of the present application. Apparently, the examples described are only part of, but not all of, the examples of the present application. All other examples obtained by those skilled in the art based on the examples in the present application without creative work shall fall in the scope of protection of the present application.

The disclosure below provides a variety of different implementations or examples to achieve different structures of the present application. In order to simplify the present application, components and settings of specific examples are described below. Of course, they are merely examples, and are not intended to limit the present application. In addition, the present application may repeat the reference numerals and/or reference letters in different examples, and such repetitions are for the purposes of simplification and clarity, and do not indicate in themselves the relationships between various implementations and/or settings as discussed. In addition, the present application provides examples of various specific processes and materials. However, those of ordinary skill in the art may realize the application of other processes and/or use of other materials.

A procedure of a SADP fabrication process is to fabricate a mandrel structure through first-time patterning, then form a gap wall at two sides of the mandrel structure, and subsequently etch an underlying material layer not covered by the gap wall by removing the mandrel structure and leaving the gap wall as a mask; or to fabricate a mandrel structure through first-time patterning, then form a gap wall at two sides of the mandrel structure, form another material layer to fully fill a remaining gap between the mandrel structures, and subsequently etch an underlying material layer exposed from a gap by taking the gap formed by removing the gap wall as an etching channel. This procedure is the SARP fabrication process.

In addition, in some semiconductor structures, there is a need to form fine structures of different lengths. However, there are still difficulties to be overcome for the current SADP technology and SARP technology due to process limitations.

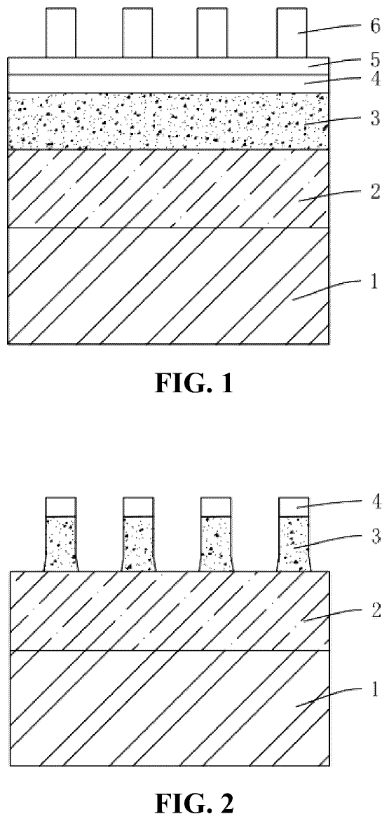

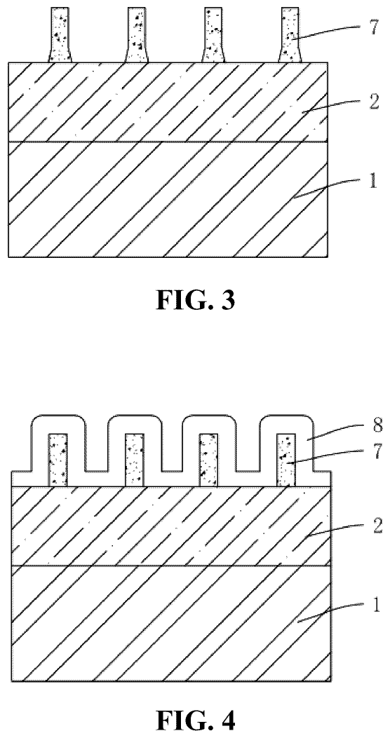

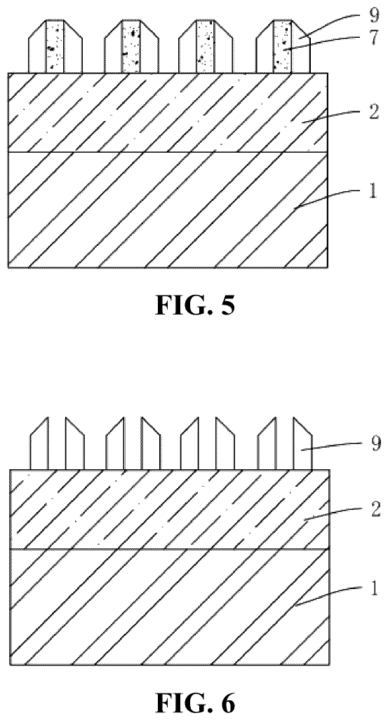

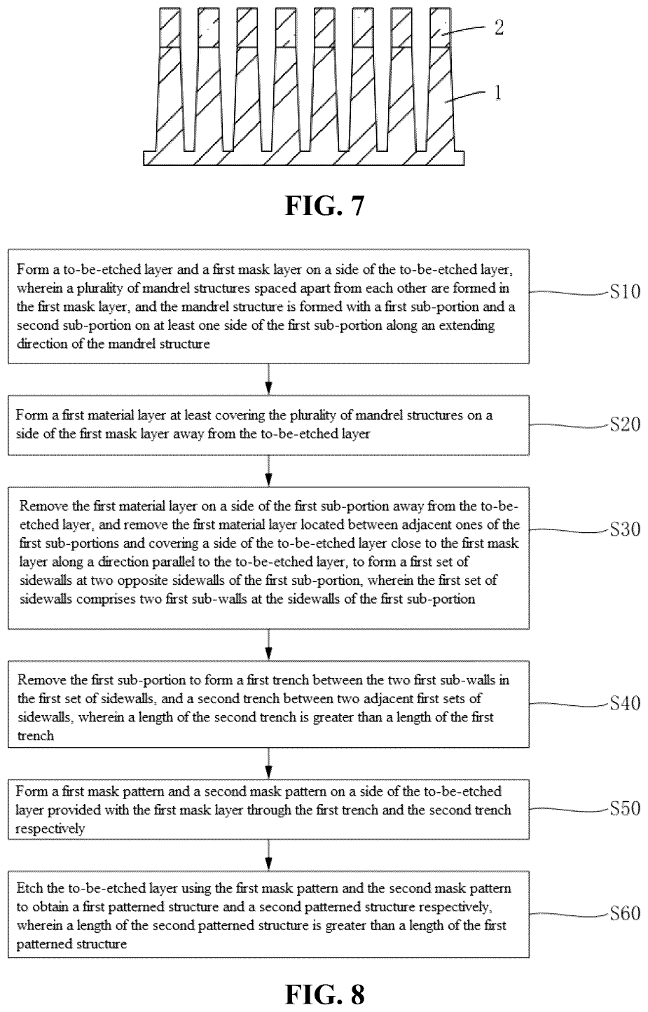

In conjunction with FIGS. 1 to 7, a patterning method provided by some examples of the present application is illustrated and comprises:
forming a substrate layer 1, a target layer 2, a transfer layer 3, a first mask layer 4, an anti-reflection layer 5 and a second mask layer 6 sequentially, as shown in FIG. 1;
patterning the first mask layer 4 and the transfer layer 3 according to a pattern of the second mask layer 6 to form a transfer layer pattern, and removing the second mask layer 6 and the anti-reflection layer 5, as shown in FIG. 2;
trimming the remaining transfer layer pattern and removing the first mask layer 4 to form a transfer pattern, i.e., mandrels 7, as shown in FIG. 3;
then forming a barrier material layer 8 covering the plurality of mandrels 7 on the target layer 2, as shown in FIG. 4;
then etching the barrier material layer 8 to form sidewalls 9 on two sides of each of the mandrels 7, as shown in FIG. 5;
removing the mandrels 7 to form the plurality of sidewalls 9 spaced apart from each other, with trenches being formed between adjacent ones of the sidewalls 9, as shown in FIG. 6; and
finally, etching the target layer 2 and the substrate layer 1 using the plurality of sidewalls 9 as a mask to form a corresponding pattern, as shown in FIG. 7. The above is a process method for forming a periodic pattern with a small size and high precision. However, the patterns fabricated using this process method are of the same size, for example, the same length, which cannot meet requirements on the fabrication of lines or trenches of different lengths.

Examples of the present application provide a patterning method, comprising:
forming a to-be-etched layer and a first mask layer on a side of the to-be-etched layer, wherein a plurality of mandrel structures spaced apart from each other are formed in the first mask layer, and the mandrel structure is formed with a first sub-portion and a second sub-portion on at least one side of the first sub-portion along an extending direction of the mandrel structure;
forming a first material layer covering the plurality of mandrel structures on a side of the first mask layer away from the to-be-etched layer;
removing the first material layer on a side of the first sub-portion away from the to-be-etched layer, and removing the first material layer located between adjacent ones of the first sub-portions and covering a side of the to-be-etched layer close to the first mask layer along a direction parallel to the to-be-etched layer to form a first set of sidewalls at two opposite sidewalls of the first sub-portion, wherein the first set of sidewalls comprises two first sub-walls at the sidewalls of the first sub-portion;
removing the first sub-portion to form a first trench between the two first sub-walls in the first set of sidewalls, and a second trench between two adjacent first sets of sidewalls, wherein a length of the second trench is greater than a length of the first trench;
forming a first mask pattern and a second mask pattern on a side of the to-be-etched layer provided with the first mask layer through the first trench and the second trench respectively; and
etching the to-be-etched layer using the first mask pattern and the second mask pattern to obtain a first patterned structure and a second patterned structure, wherein a length of the second patterned structure is greater than a length of the first patterned structure.

According to the examples of the present application, by removing part of the mandrel structure after forming the first material layer, the first trench with the smaller length and the second trench with the greater length are formed, and the first mask pattern and the second mask pattern may be formed through the first trench and the second trench so as to form the first patterned structure and the second patterned structure of different lengths. Further, the applicability of the patterning method can be improved, and the process difficulty and cost of fine patterning for forming patterns of different sizes are reduced, such that the patterning method provided by the present application can meet more process requirements.

With reference to FIGS. 8, 9 and 30, in one example of the present application, the patterning method comprises:
S10, forming a to-be-etched layer 10 and a first mask layer 20 on a side of the to-be-etched layer 10, wherein a plurality of mandrel structures 21 spaced apart from each other are formed in the first mask layer 20, and the mandrel structure 21 is formed with a first sub-portion 211 and a second sub-portion 212 on at least one side of the first sub-portion 211 along an extending direction of the mandrel structure 21.

In operation S10, first, a second mask layer 40 and the first mask layer 20 are formed on a side of the to-be-etched layer 10, wherein the second mask layer 40 is located between the to-be-etched layer 10 and the first mask layer 20.

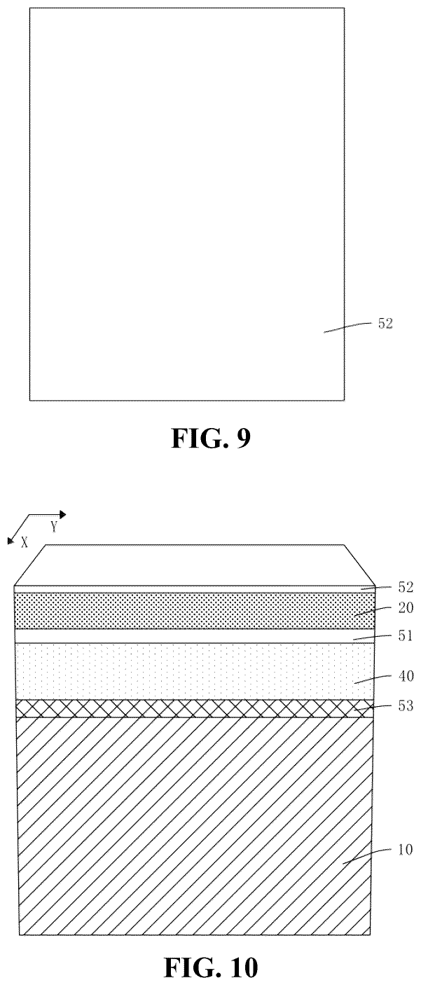

In some examples, operation S10 further comprises forming an auxiliary mask layer 53 between the to-be-etched layer 10 and the second mask layer 40, forming a first anti-reflection layer 51 between the second mask layer 40 and the first mask layer 20, and forming a second anti-reflection layer 52 on a side of the first mask layer 20 away from the second mask layer 40, as shown in FIGS. 9 and 10. During a subsequent etching process for the above-mentioned stack structure, the first anti-reflection layer 51 and the second anti-reflection layer 52 can improve a standing wave effect and a notching effect of photoresist, while the auxiliary mask layer 53 can improve the film layer morphology of the to-be-etched layer 10 during the etching process.

In some examples, a material of the to-be-etched layer 10 may comprise a metal material, a semiconductor material or other etchable materials. Materials of the first mask layer 20, the second mask layer 40 and the auxiliary mask layer 53 may each independently comprise an oxide material or a nitride material, for example, at least one of plasma enhanced oxide (PEOX), thermal oxide, chemical vapor deposition (CVD) oxide, undoped silicate glass (USG) or high-density plasma (HDP) oxide, or silicon oxynitride (SiON), silicon nitride (SiN), silicon boron nitride (SiBN) or boron nitride. The first anti-reflection layer 51 and the second anti-reflection layer 52 may consist of a bottom anti-reflection coating (BARC) film.

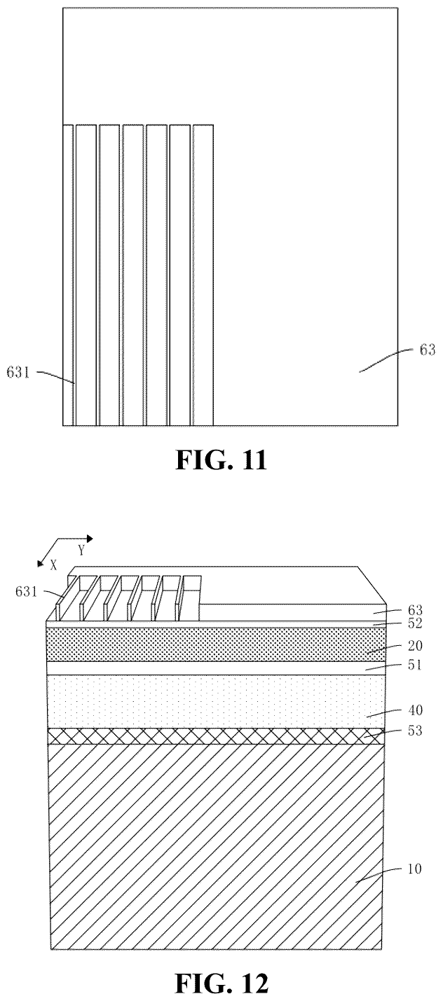

Then, a third photoresist layer 63 is formed on a side of the second anti-reflection layer 52 away from the first mask layer 20, and a preset pattern which, for example, may be a plurality of photoresist sidewalls 631 disposed as being spaced apart, is formed in the third photoresist layer 63, as shown in FIGS. 11 and 12.

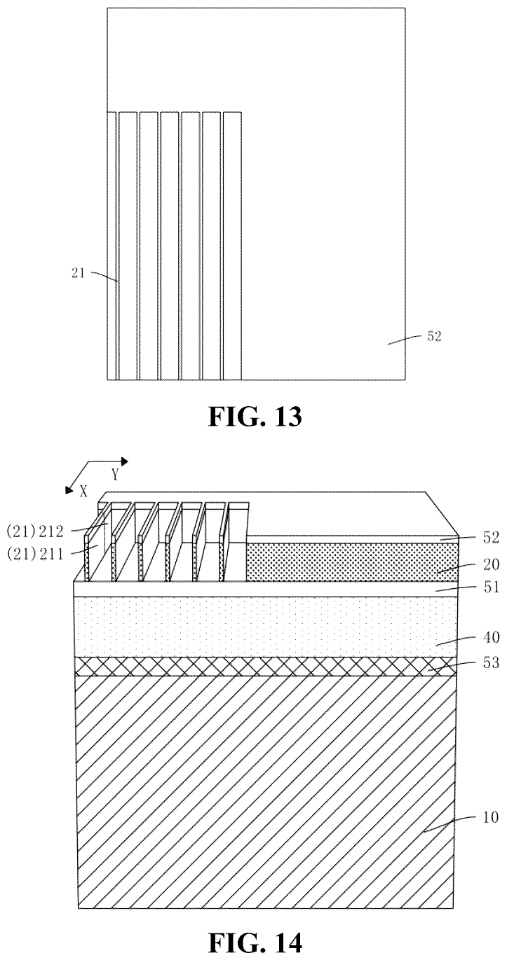

Next, patterning is performed on the second anti-reflection layer 52 and the first mask layer 20 through the third photoresist layer 63, to remove the second anti-reflection layer 52 and the first mask layer 20 not covered by the third photoresist layer 63 by etching. Further, the plurality of mandrel structures 21 disposed as being spaced apart may be formed in the first mask layer 20. It may be understood that, a side of each mandrel structure 21 away from the first anti-reflection layer 51 is covered with part of the second anti-reflection layer 52, as shown in FIGS. 13 and 14.

It is to be noted that the plurality of mandrel structures 21 comprise the first sub-portions 211 and the second sub-portions 212 connected with at least one side of the mandrel structures 21 along the extending direction of the mandrel structures 21, wherein the extending direction of the mandrel structures 21 is a direction X.
S20, forming a first material layer 30 covering the plurality of mandrel structures 21 on a side of the first mask layer 20 away from the to-be-etched layer 10.

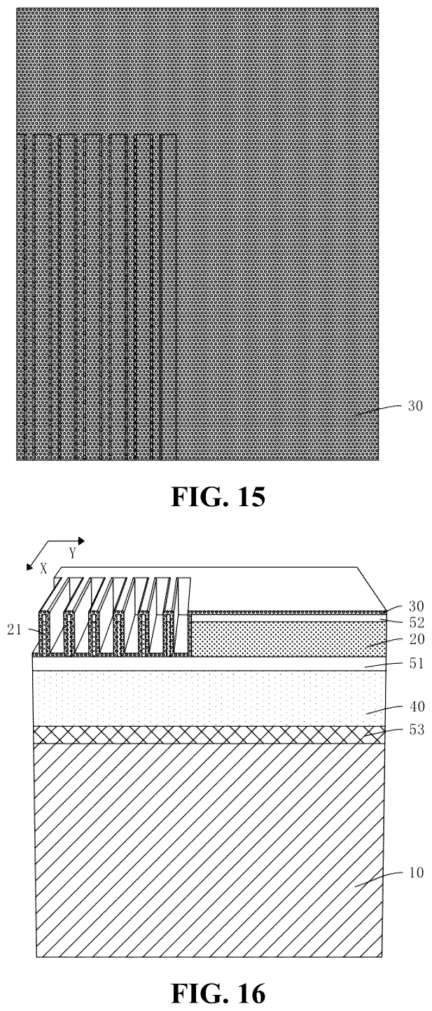

In operation S20, the first material layer 30 is formed on a side of the second anti-reflection layer 52 away from the first anti-reflection layer 51, and the first material layer 30 covers a surface on the side of the second anti-reflection layer 52 away from the first anti-reflection layer 51, sidewalls of the plurality of mandrel structures 21 and a region between the adjacent mandrel structures 21, as shown in FIGS. 15 and 16.

In some examples, a material of the first material layer 30 comprises an oxide material or a nitride material, and may be different from the materials of the first mask layer 20 and the second mask layer 40. For example, if the materials of the first mask layer 20 and the second mask layer 40 are the oxide material, the material of the first material layer 30 is the nitride material. If the materials of the first mask layer 20 and the second mask layer 40 are the nitride material, the material of the first material layer 30 is the oxide material.

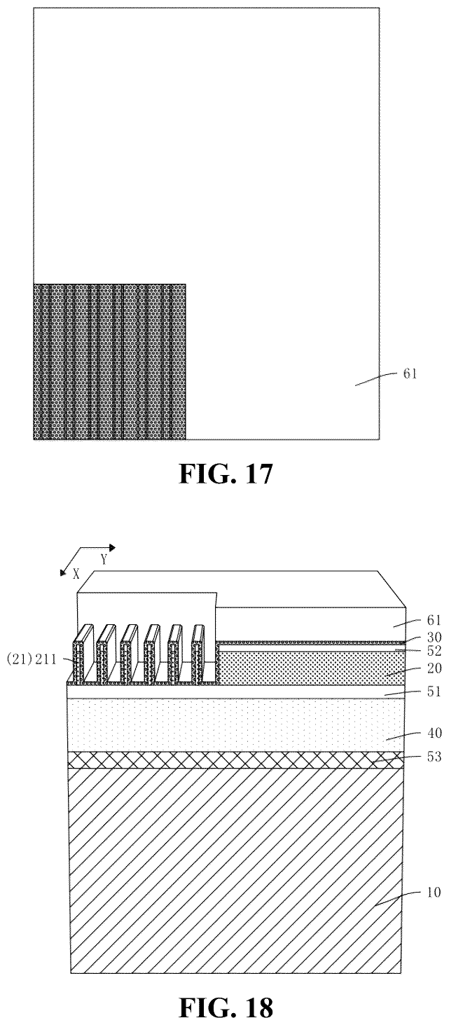

Then, a first photoresist layer 61 is formed on a side of the first material layer 30 away from the second anti-reflection layer 52, and a preset pattern is formed in the first photoresist layer 61 to cover part of an underlying film layer. In an example, the first sub-portion 211 is located outside coverage of the first photoresist layer 61, and the second sub-portion 212 and the other portion of the first mask layer 20 are both located within the coverage of the first photoresist layer 61, as shown in FIGS. 14, 17 and 18.
S30, removing the first material layer 30 on a side of the first sub-portion 211 away from the to-be-etched layer 10, and removing the first material layer 30 located between adjacent ones of the first sub-portions 211 and covering a side of the to-be-etched layer 10 close to the first mask layer 20 along a direction parallel to the to-be-etched layer 10, to form a first set of sidewalls 31 at two opposite sidewalls of the first sub-portion 211, wherein the first set of sidewalls 31 comprises two first sub-walls 311 at the sidewalls of the first sub-portion 211.

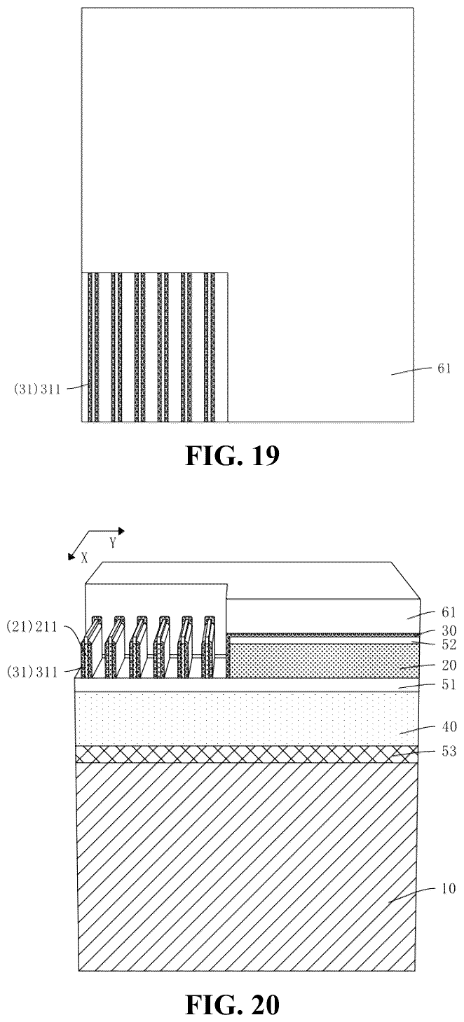

In operation S30, the first material layer 30 is etched using an anisotropic etching process, i.e., to remove the first material layer 30 extending and covering along the direction parallel to the to-be-etched layer 10 and located outside the coverage of the first photoresist layer 61, wherein the direction parallel to the to-be-etched layer 10 is a direction Y. In an example, the first material layer 30 on the side of the first sub-portion 211 away from the to-be-etched layer 10 is removed, and the first material layer 30 located between adjacent ones of the first sub-portions 211 and covering the side of the to-be-etched layer 10 close to the first mask layer 20 along the direction parallel to the to-be-etched layer 10 is removed, such that the first set of sidewalls 31 may be formed at the two opposite sidewalls of the first sub-portion 211, wherein the first set of sidewalls 31 comprises the two first sub-walls 311 at the sidewalls of the first sub-portion 211, as shown in FIGS. 19 and 20.
S40, removing the first sub-portion 211 to form a first trench 310 between the two first sub-walls 311 in the first set of sidewalls 31, and a second trench 320 between two adjacent first sets of sidewalls 31, wherein a length of the second trench 320 is greater than a length of the first trench 310.

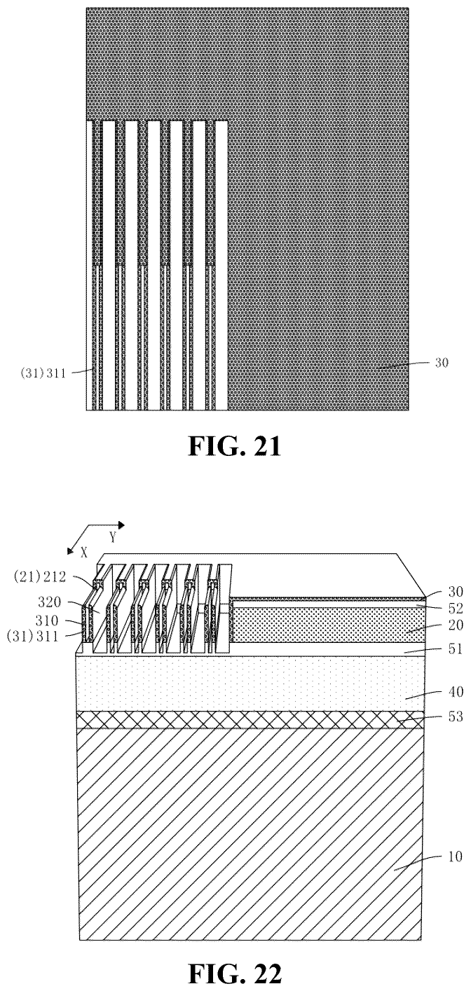

In operation S40, first, the first photoresist layer 61 is removed, and then the first sub-portion 211 is removed, as shown in FIGS. 21 and 22.

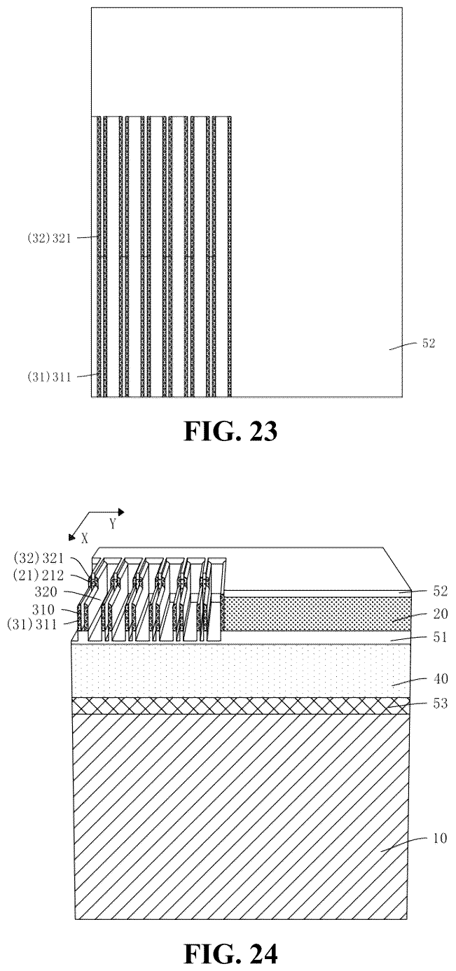

Then, anisotropic etching is performed on the remaining first material layer 30, that is, the first material layer 30 extending and covering along the direction parallel to the to-be-etched layer 10 is removed. In an example, the first material layer 30 on a side of the second sub-portion 212 away from the to-be-etched layer 10 is removed, and the first material layer 30 located between adjacent ones of the second sub-portions 212 and covering the side of the to-be-etched layer 10 close to the first mask layer 20 along the direction parallel to the to-be-etched layer 10 is removed, such that a second set of sidewalls 32 may be formed at two opposite sidewalls of the second sub-portion 212, wherein the second set of sidewalls 32 comprises two second sub-walls 321 at the sidewalls of the second sub-portion 212, as shown in FIGS. 23 and 24.

Then, the second sub-portion 212 is removed to form the second trench 320 between adjacent second sets of sidewalls 32, and form the first trench 310 between the two first sub-walls 311 in the first set of sidewalls 31. Moreover, the first anti-reflection layer 51 on the side of the first mask layer 20 away from the to-be-etched layer 10 is left between the two second sub-walls 321 in the second set of sidewalls 32, as shown in FIGS. 24, 25 and 26.

The length of the second trench 320 is greater than the length of the first trench 310. In some examples, the length of the second trench 320 may be equal to a length of the mandrel structure 21 along the extending direction thereof, while the length of the first trench 310 may be equal to a length of the first sub-portion 211 along the extending direction of the mandrel structure 21.

It is to be noted that the first trench 310 is formed between the two first sub-walls 311 in the first set of sidewalls 31, and in a structure corresponding to FIGS. 22 and 24, the first anti-reflection layer 51 is also left at the bottom of the first trench 310; and the second trench 320 is formed between the adjacent second sets of sidewalls 32, and in a structure corresponding to FIGS. 22 and 24, the first anti-reflection layer 51 is left at the bottom of the second trench 320 as well.

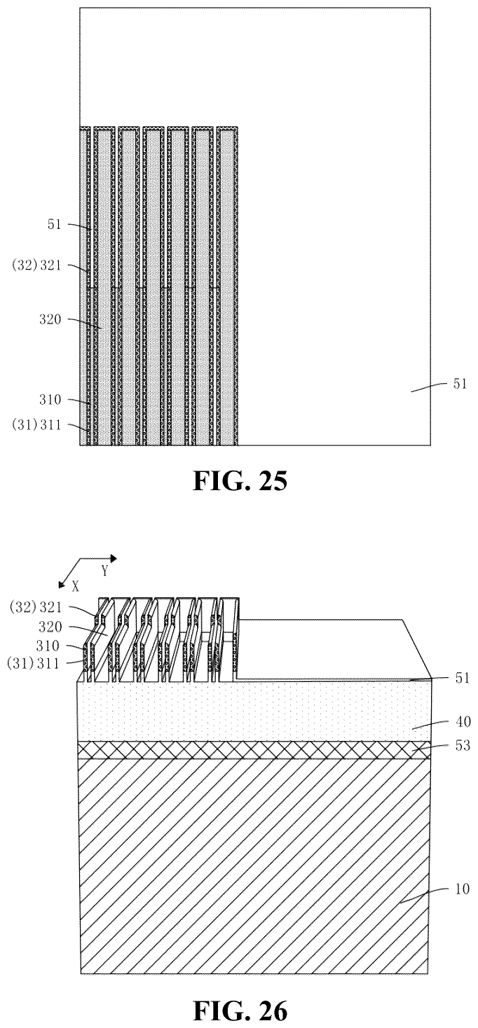

Further, in an operation from the structure shown in FIG. 24 to the structure shown in FIG. 26, the second sub-portion 212, the first anti-reflection layer 51 at the bottom of the first trench 310 and the first anti-reflection layer 51 at the bottom of the second trench 320 need to be removed. However, the first anti-reflection layer 51 on the side of the first mask layer 20 away from the to-be-etched layer 10 is left between the two second sub-walls 321 in the second set of sidewalls 32, the first sub-wall 311, the second sub-wall 321 and the second mask layer 40 are all provided with the first anti-reflection layer 51 disposed as being spaced apart, and a region except the first trench 310 and the second trench 320 is covered with the first anti-reflection layer 51, that is, in the structure shown in FIG. 26, a surface on a side of the second mask layer 40 away from the to-be-etched layer 10 is exposed only at the first trench 310 and the second trench 320.
S50, forming a first mask pattern 41 and a second mask pattern 42 on a side of the to-be-etched layer 10 provided with the first mask layer 20 through the first trench 310 and the second trench 320 respectively.

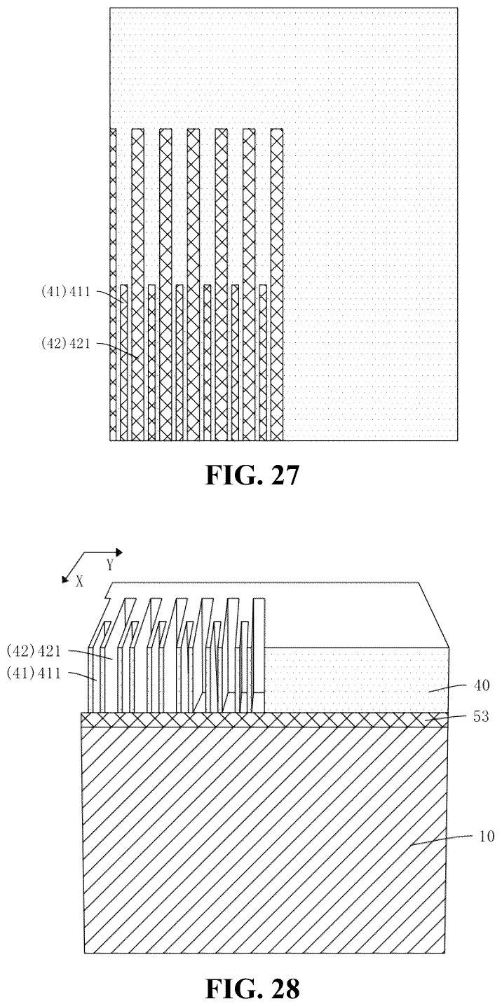

In operation S50, etching is performed on the second mask layer 40 using the first set of sidewalls 31, the second set of sidewalls 32 and the first anti-reflection layer 51 as a mask, so as to remove the second mask layer 40 corresponding to the first trench 310, and to remove the second mask layer 40 corresponding to the second trench 320, and then the first mask pattern 41 and the second mask pattern 42 are formed in the second mask layer 40 respectively, as shown in FIGS. 27 and 28.

The first mask pattern 41 may be a first mask groove 411 formed in the second mask layer 40, the second mask pattern 42 may be a second mask groove 421 formed in the second mask layer 40, and a length of the second mask groove 421 is greater than a length of the first mask groove 411.
S60, etching the to-be-etched layer 10 using the first mask pattern 41 and the second mask pattern 42 to obtain a first patterned structure 11 and a second patterned structure 12, wherein a length of the second patterned structure 12 is greater than a length of the first patterned structure 11.

In operation S60, the to-be-etched layer 10 and the auxiliary mask layer 53 are etched using the first mask pattern 41 and the second mask pattern 42, to form the first patterned structure 11 and the second patterned structure 12 in the to-be-etched layer 10 respectively.

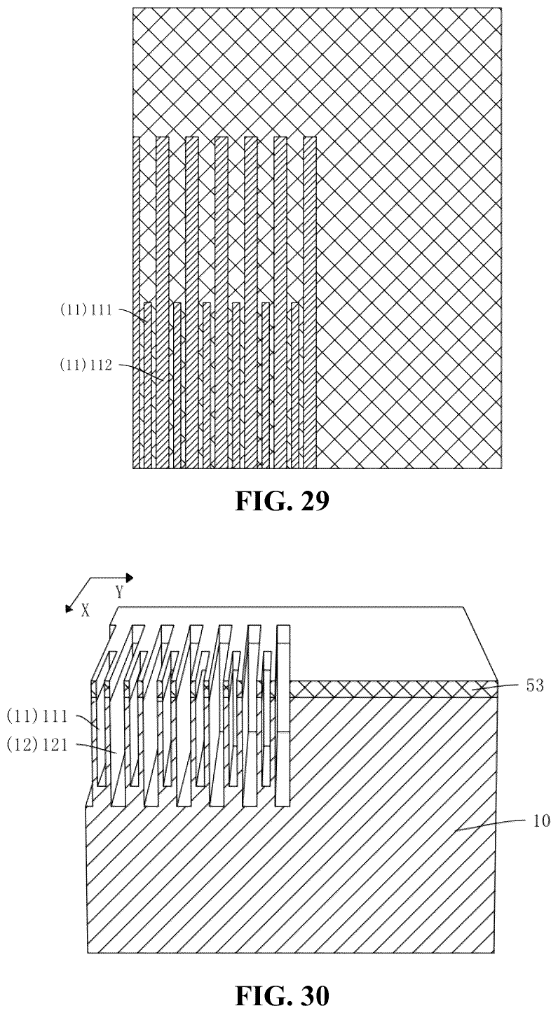

The first patterned structure 11 may be a first groove 111 formed in the to-be-etched layer 10, and the second patterned structure 12 may be a second groove 121 formed in the to-be-etched layer 10, as shown in FIGS. 29 and 30.

It is to be noted that, since the first groove 111 is formed corresponding to the first mask pattern 41, i.e., formed corresponding to the first trench 310, and the second groove 121 is formed corresponding to the second mask pattern 42, i.e., formed corresponding to the second trench 320, a length of the second groove 121 is greater than a length of the first groove 111.

In some examples, the length of the second groove 121 may be equal to the length of the mandrel structure 21 along the extending direction thereof, and the length of the first groove 111 may be equal to the length of the first sub-portion 211 along the extending direction of the mandrel structure 21.

In some examples of the present application, the mandrel structure 21 may be partially shielded by disposition of the first photoresist layer 61, and part of the mandrel structure 21 is removed to form the first trench 310 with the smaller length and the second trench 320 with the greater length, and the first mask pattern 41 and the second mask pattern 42 may be formed through the first trench 310 and the second trench 320 so as to form the first patterned structure 11 and the second patterned structure 12 of different lengths. Further, the applicability of the patterning method can be improved, and the process difficulty and cost of fine patterning for forming patterns of different sizes are reduced, such that the patterning method provided by the present application can meet more process requirements.

In addition, with reference to FIGS. 8, and 31 to 46, in another example of the present application, the patterning method comprises:
S10, forming a to-be-etched layer 10 and a first mask layer 20 on a side of the to-be-etched layer 10, wherein a plurality of mandrel structures 21 spaced apart from each other are formed in the first mask layer 20, and the mandrel structure 21 is formed with a first sub-portion 211 and a second sub-portion 212 on at least one side of the first sub-portion 211 along an extending direction of the mandrel structure 21.

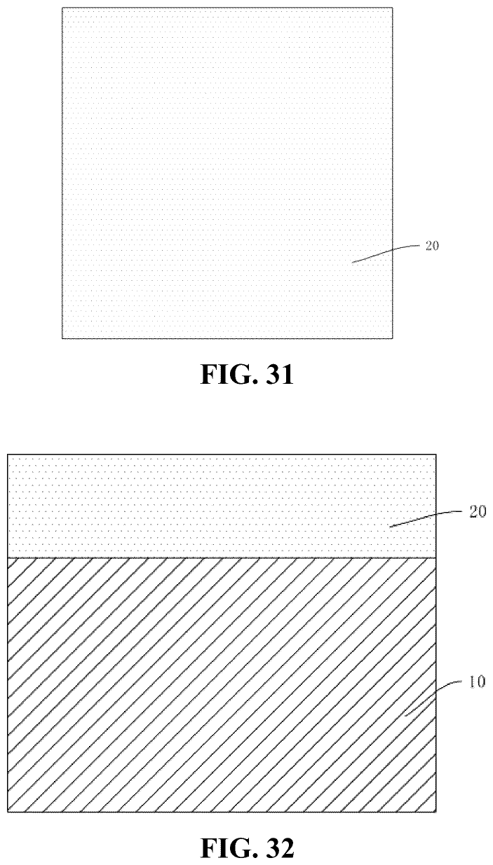

In operation S10, first, the to-be-etched layer 10 is formed, and then the first mask layer 20 is formed on the side of the to-be-etched layer 10, as shown in FIGS. 31 and 32.

In some examples, a material of the to-be-etched layer 10 may comprise a metal material, a semiconductor material or other etchable materials. A material of the first mask layer 20 may separately comprise an oxide material or a nitride material, for example, at least one of plasma enhanced oxide (PEOX), thermal oxide, chemical vapor deposition (CVD) oxide, undoped silicate glass (USG) or high-density plasma (HDP) oxides, or silicon oxynitride (SiON), silicon nitride (SiN), silicon boron nitride (SiBN) or boron nitride.

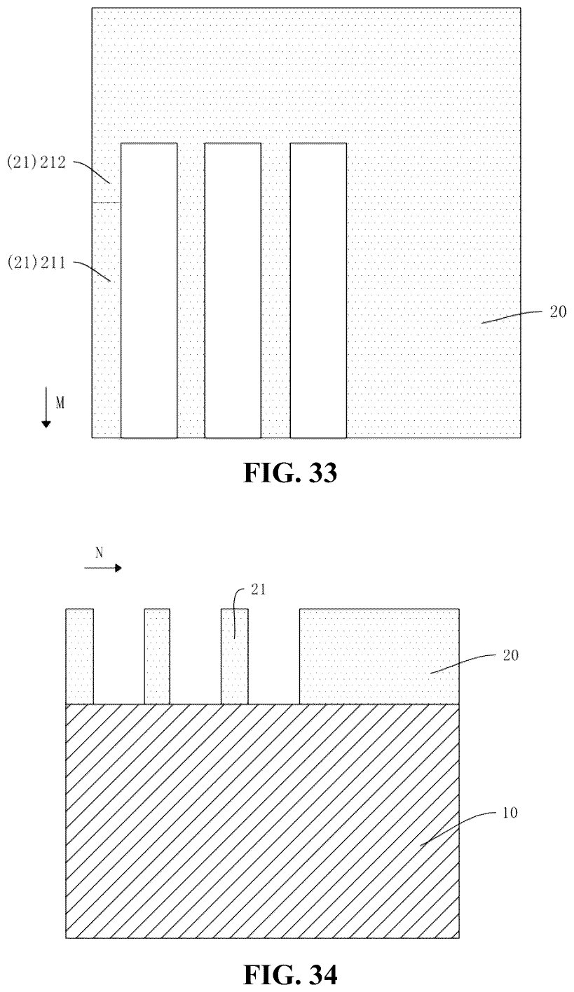

Then, the first mask layer 20 is etched to form the plurality of mandrel structures 21 disposed as being spaced apart, the mandrel structure 21 is formed with the first sub-portion 211 and the second sub-portion 212 on at least one side of the first sub-portion 211 along an extending direction of the mandrel structure 21, and the extending direction of the mandrel structure 21 is a direction M, as shown in FIGS. 33 and 34.
S20, forming a first material layer 30 covering the plurality of mandrel structures 21 on a side of the first mask layer 20 away from the to-be-etched layer 10.

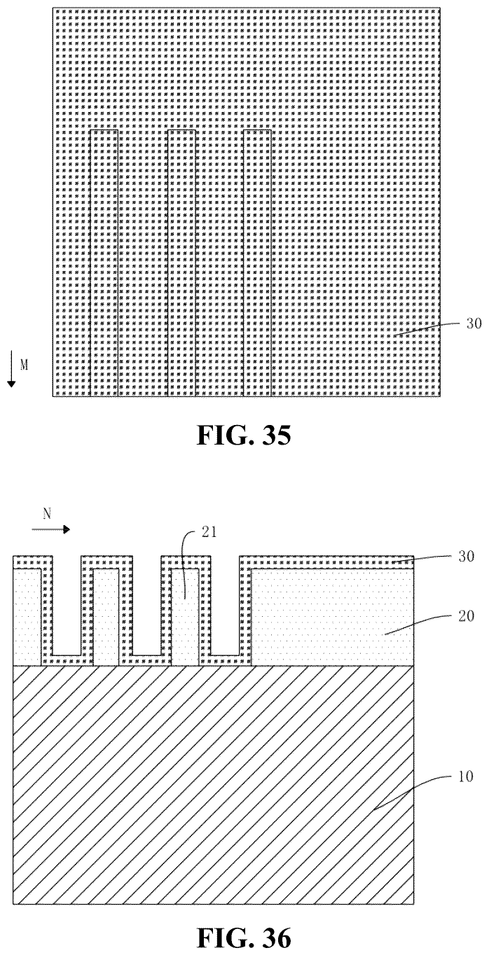

In operation S20, the first material layer 30 is formed on the side of the first mask layer 20 away from the to-be-etched layer 10, and the first material layer 30 covers the plurality of mandrel structures 21, and in an example, the first material layer 30 may cover a top face and a sidewall of the mandrel structure 21, and cover a region between adjacent ones of the mandrel structures 21, as shown in FIGS. 35 and 36.

In some examples, a material of the first material layer 30 comprises an oxide material or a nitride material, and may be different from the material of the first mask layer 20. For example, if the material of the first mask layer 20 is the oxide material, the material of the first material layer 30 is the nitride material. If the material of the first mask layer 20 is the nitride material, the material of the first material layer 30 is the oxide material.

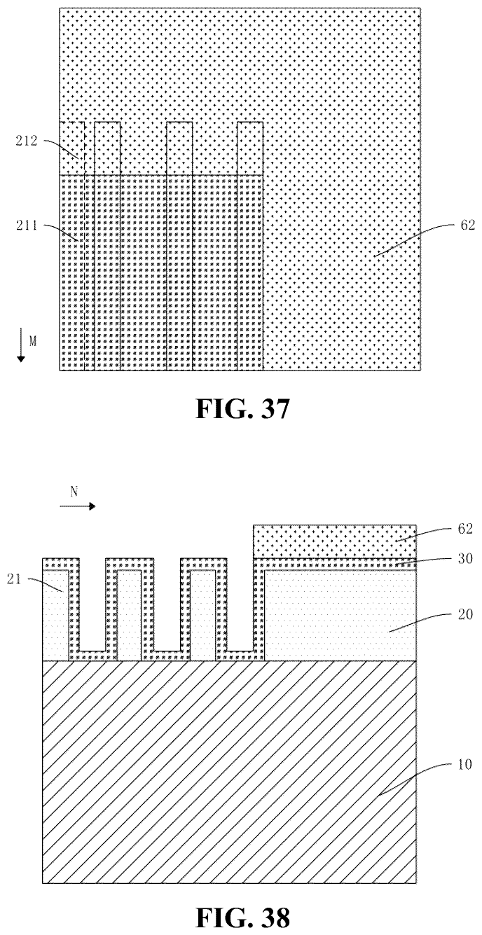

A second photoresist layer 62 is formed on a side of the first material layer 30 away from the first mask layer 20, wherein the first sub-portion 211 is located outside coverage of the second photoresist layer 62, and the second sub-portion 212 and the other portion of the first material layer 30 are located within the coverage of the second photoresist layer 62, as shown in FIGS. 37 and 38.
S30, removing the first material layer 30 on a side of the first sub-portion 211 away from the to-be-etched layer 10, and removing the first material layer 30 located between adjacent ones of the first sub-portions 211 and covering a side of the to-be-etched layer 10 close to the first mask layer 20 along a direction parallel to the to-be-etched layer 10, to form a first set of sidewalls 31 at two opposite sidewalls of the first sub-portion 211, wherein the first set of sidewalls 31 comprises two first sub-walls 311 at the sidewalls of the first sub-portion 211.

In operation S30, the first material layer 30 is etched using an anisotropic etching process to remove the first material layer 30 on the side of the first sub-portion 211 away from the to-be-etched layer 10, and remove the first material layer 30 located between the adjacent ones of the first sub-portions 211 and covering the side of the to-be-etched layer 10 close to the first mask layer 20 along the direction parallel to the to-be-etched layer 10, wherein the direction parallel to the to-be-etched layer 10 is a direction N; and the first set of sidewalls 31 is formed at the two opposite sidewalls of the first sub-portion 211 and comprises the two first sub-walls 311 at the sidewalls of the first sub-portion 211.

Then, the second photoresist layer 62 is removed.
S40, removing the first sub-portion 211 to form a first trench 310 between the two first sub-walls 311 in the first set of sidewalls 31, and a second trench 320 between two adjacent first sets of sidewalls 31, wherein a length of the second trench 320 is greater than a length of the first trench 310.

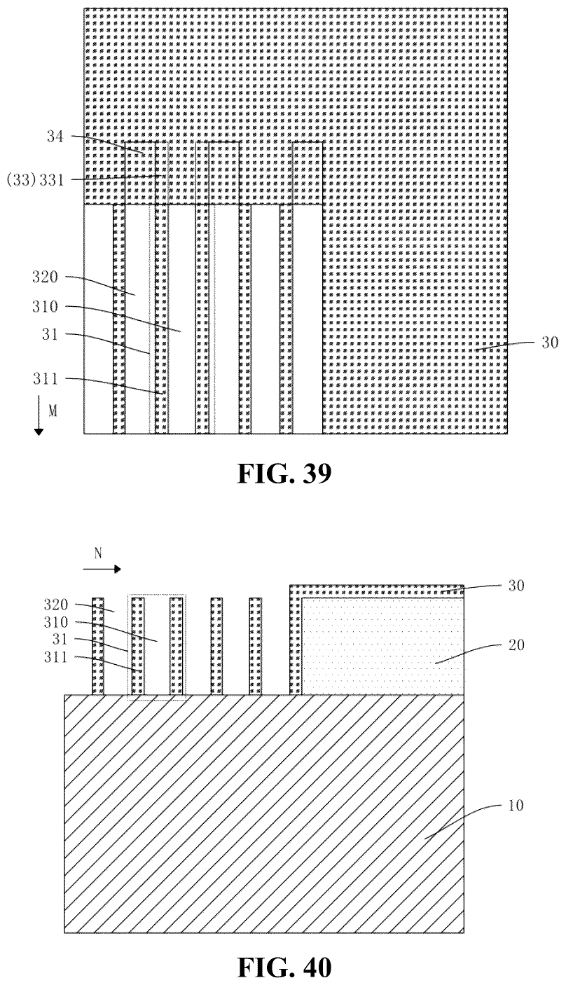

In operation S40, the first sub-portion 211 is removed to form the first trench 310 between the two first sub-walls 311 in the first set of sidewalls 31 and form the second trench 320 between the adjacent first sets of sidewalls 31, as shown in FIGS. 39 and 40.

It may be understood that, the length of the second trench 320 is greater than the length of the first trench 310. In some examples, the length of the second trench 320 may be equal to the length of the mandrel structure 21 along the extending direction thereof, and the length of the first trench 310 may be equal to the length of the first sub-portion 211 along the extending direction of the mandrel structure 21.

It is to be noted that, the first material layer 30 covers the second sub-portion 212, and a third set of sidewalls 33 is formed at two opposite sidewalls of the second sub-portion 212, and comprises two third sub-walls 331 at the sidewalls of the second sub-portion 212, while the second trench 320 is also formed between adjacent third sets of sidewalls 33. In addition, the first material layer 30 is further formed with a spacer portion 34 located between the two adjacent third sets of sidewalls 33 in the second trench 320.
S50, forming a first mask pattern 41 and a second mask pattern 42 on a side of the to-be-etched layer 10 provided with the first mask layer 20 through the first trench 310 and the second trench 320 respectively.

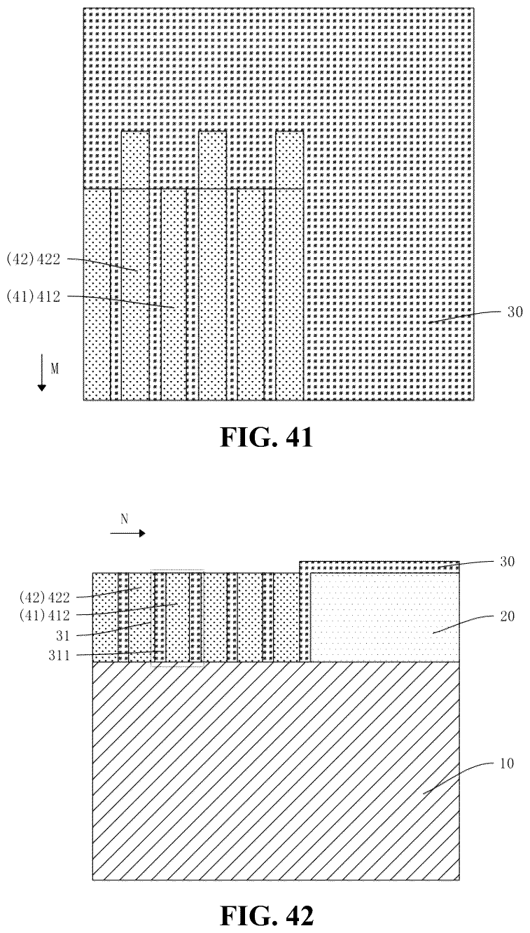

In operation S50, the first mask pattern 41 and the second mask pattern 42 are formed in the first trench 310 and the second trench 320 respectively. In an example, the first mask pattern 41 may be a first mask sidewall 412 formed in the first trench 310, the second mask pattern 42 may be a second mask sidewall 422 formed in the second trench 320, and a length of the second mask sidewall 422 is greater than a length of the first mask sidewall 412, as shown in FIGS. 41 and 42.

It is to be noted that, in the second trench 320, the second mask sidewall 422 between the adjacent first sets of sidewalls 31 covers the to-be-etched layer 10, and the second mask sidewall 422 between the adjacent third sets of sidewalls 33 covers the spacer portion 34.

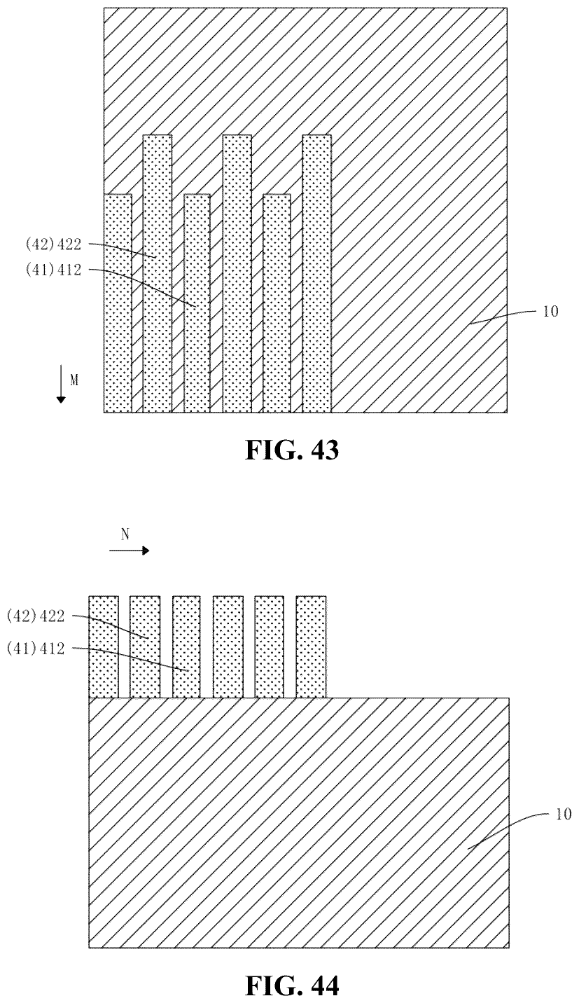

Then, the first material layer 30 except the spacer portion 34 is removed to form the first mask sidewall 412 and the second mask sidewall 422 disposed as being spaced apart on the to-be-etched layer 10, as shown in FIGS. 43 and 44.
S60, etching the to-be-etched layer 10 using the first mask pattern 41 and the second mask pattern 42 to obtain a first patterned structure 11 and a second patterned structure 12, wherein a length of the second patterned structure 12 is greater than a length of the first patterned structure 11.

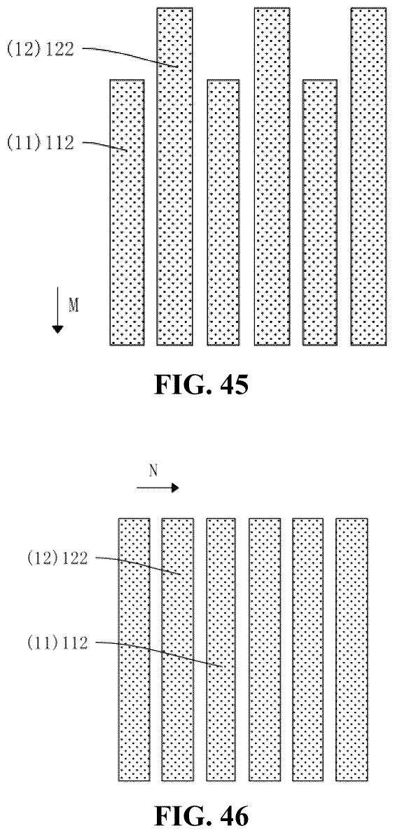

In operation S60, the to-be-etched layer 10 not covered by the first mask sidewall 412 and the second mask sidewall 422 is removed to form the first patterned structure 11 and the second patterned structure 12 respectively, wherein the first patterned structure 11 is a first route 112 formed corresponding to the first mask sidewall 412, and the second patterned structure 12 is a second route 122 formed corresponding to the second mask sidewall 422, as shown in FIGS. 45 and 46.

It is to be noted that, a length of the second route 122 is greater than a length of the first route 112; the first route 112 is formed corresponding to the first mask sidewall 412, that is, the first route 112 is formed corresponding to the first trench 310; and the second route 122 is formed corresponding to the second mask sidewall 422, that is, the second route 122 is formed corresponding to the second trench 320, such that in some examples, the length of the second route 122 may be equal to the length of the mandrel structure 21 along the extending direction thereof, and the length of the first route 112 may be equal to the length of the first sub-portion 211 along the extending direction of the mandrel structure 21.

In some examples of the present application, the mandrel structure 21 may be partially shielded by disposition of a second photoresist layer 62, and part of the mandrel structure 21 is removed to form the first trench 310 with the smaller length and the second trench 320 with the greater length, and the first mask pattern 41 and the second mask pattern 42 may be formed using the first trench 310 and the second trench 320 so as to form the first patterned structure 11 and the second patterned structure 12 of different lengths. Further, the applicability of the patterning method can be improved, and the process difficulty and cost of fine patterning for forming patterns of different sizes are reduced, such that the patterning method provided by the present application can meet more process requirements.

It is to be noted that in the examples of the present application, the patterned structures, for example, the grooves or the routes, of different lengths may be fabricated through the patterning method as described in the above examples, and the grooves or the routes of different lengths may be a plurality of grooves or routes which are aligned at one end and not aligned at the other end, or a plurality of grooves or routes which are not aligned at both ends. When the second sub-portion 212 is connected with a side of the first sub-portion 211 along the extending direction of the mandrel structure 21, the above-mentioned patterning method may form a plurality of grooves or routes which are aligned at one end and not aligned at the other end; and when the second sub-portion 212 is connected with two opposite sides of the first sub-portion 211 along the extending direction of the mandrel structure 21, the above-mentioned patterning method can form a plurality of grooves or routes which are not aligned at both ends.

In addition, examples of the present application further provide a semiconductor structure that is fabricated using the patterning method as described in the above examples.

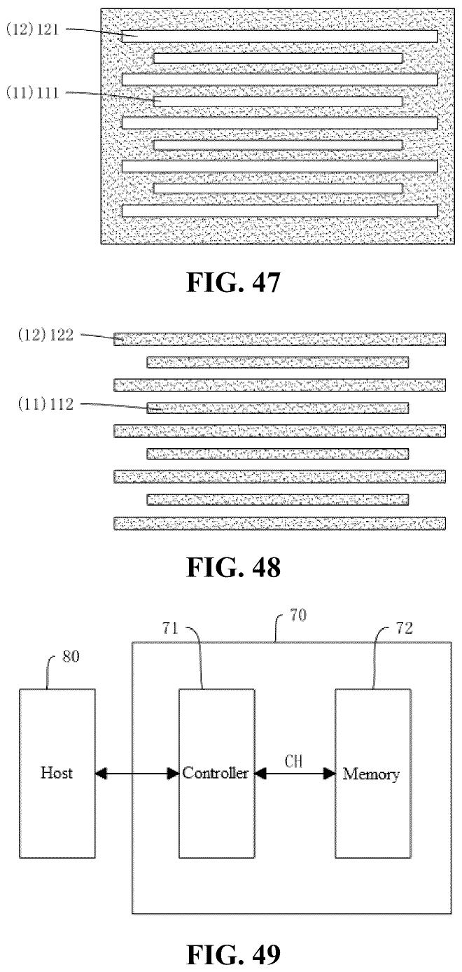

In some examples, with reference to FIG. 47, a first groove 111 and a second groove 121 are disposed in the semiconductor structure, and a length of the second groove 121 is greater than a length of the first groove 111. The first groove 111 and the second groove 121 may be formed using a first patterned structure 11 and a second patterned structure 12 fabricated by the patterning method as described in the above examples respectively.

In some examples, with reference to FIG. 48, a first route 112 and a second route 122 are disposed in the semiconductor structure, and a length of the second route 122 is greater than a length of the first route 112. The first route 112 and the second route 122 may be formed using a first patterned structure 11 and a second patterned structure 12 fabricated by the patterning method as described in the above examples respectively.

Further, examples of the present application further provide a memory and a memory system. The memory comprises the semiconductor structure as described in the above examples.

The memory system comprises the above-mentioned semiconductor structure. With reference to FIG. 49, the memory system comprises a memory 72 and a controller 71, wherein the controller 71 is coupled to the memory 72 and configured to control the memory 72 to store data, and the memory 72 is a memory fabricated by a fabrication method of the memory as described in the above examples or the memory as described in the above examples.

In an example, the controller 71 may control the memory 72 through a channel CH, and the memory 72 may perform operations based on control of the controller 71 in response to a request from a host 80. The memory 72 may receive a command CMD and an address ADDR from the controller 71 through the channel CH, and access a region selected from a memory array in response to the address. In other words, the memory 72 may perform an internal operation corresponding to the command on the region selected by the address.

In some examples, the memory system may be implemented to include, but not limited to, a Universal Flash Storage (UFS) device, a solid-state drive (SSD), a multi-media card of MMC, eMMC, RS-MMC and micro-MMC forms, a secure digital card of SD, mini-SD and micro-SD forms, a memory device of a Personal Computer Memory Card International Association (PCMCIA) card type, a memory device of a Peripheral Component Interconnection (PCI) type, a memory device of a PCI-Express (PCI-E) type, a Compact Flash (CF) card, a smart media card, or a memory stick, etc.

In an example, the above-mentioned memory system may be applied to end products, such as a computer, a television, a set-top box, a vehicle-mounted product, etc.

Further, some examples of the present application also provide an electronic apparatus which comprises the above-mentioned memory system provided in the examples of the present application. In an example, the electronic apparatus may include, but not limited to, any apparatus that may store data, such as a mobile phone, a desktop computer, a tablet, a notebook computer, a server, a vehicle apparatus, a wearable apparatus, a mobile power supply, etc.

The electronic apparatus provided by some examples of the present application has the same advantageous effect as the above-mentioned memory system since it is disposed with the memory system provided by some examples of the present application.

Examples of the present application provide a patterning method, a semiconductor structure and a memory, and can obtain a first patterned structure and a second patterned structure of different lengths.

Examples of the present application provide a patterning method, comprising:
forming a to-be-etched layer and a first mask layer on a side of the to-be-etched layer, wherein a plurality of mandrel structures spaced apart from each other are formed in the first mask layer, and the mandrel structure is formed with a first sub-portion and a second sub-portion on at least one side of the first sub-portion along an extending direction of the mandrel structure;
forming a first material layer covering the plurality of mandrel structures on a side of the first mask layer away from the to-be-etched layer;
removing the first material layer on a side of the first sub-portion away from the to-be-etched layer, and removing the first material layer located between adjacent ones of the first sub-portions and covering a side of the to-be-etched layer close to the first mask layer along a direction parallel to the to-be-etched layer, to form a first set of sidewalls at two opposite sidewalls of the first sub-portion, wherein the first set of sidewalls comprises two first sub-walls at the sidewalls of the first sub-portion;
removing the first sub-portion to form a first trench between the two first sub-walls in the first set of sidewalls, and a second trench between two adjacent ones of the first sets of sidewalls, wherein a length of the second trench is greater than a length of the first trench;
forming a first mask pattern and a second mask pattern on a side of the to-be-etched layer provided with the first mask layer through the first trench and the second trench respectively; and
etching the to-be-etched layer using the first mask pattern and the second mask pattern to obtain a first patterned structure and a second patterned structure, wherein a length of the second patterned structure is greater than a length of the first patterned structure.

In one example of the present application, the forming the to-be-etched layer and the first mask layer on a side of the to-be-etched layer further comprises:
forming, on a side of the to-be-etched layer, a second mask layer and a first anti-reflection layer located on a side of the second mask layer away from the to-be-etched layer; and
forming the first mask layer on a side of the first anti-reflection layer away from the second mask layer, and patterning the first mask layer to form the plurality of mandrel structures spaced apart from each other.

In one example of the present application, the forming the first material layer covering the plurality of mandrel structures on the side of the first mask layer away from the to-be-etched layer further comprises:
forming the first material layer covering the plurality of mandrel structures on a side of the first mask layer away from the first anti-reflection layer; and
forming a first photoresist layer on a side of the first material layer away from the first mask layer, wherein the first sub-portion is located outside coverage of the first photoresist layer, and the second sub-portion is located within the coverage of the first photoresist layer.

In one example of the present application, the removing the first sub-portion further comprises:
removing the first photoresist layer;
removing the first sub-portion, with the first anti-reflection layer being left at the bottom of the first trench and the first anti-reflection layer being left at the bottom of the second trench; and
removing the first material layer on a side of the second sub-portion away from the to-be-etched layer, and removing the first material layer located between adjacent ones of the second sub-portions and covering the side of the to-be-etched layer close to the first mask layer along the direction parallel to the to-be-etched layer, to form a second set of sidewalls at two opposite sidewalls of the second sub-portion, wherein the second set of sidewalls comprises two second sub-walls at the sidewalls of the second sub-portion, and the second trench is also located between adjacent ones of the second sets of sidewalls.

In one example of the present application, the removing the first material layer on the side of the second sub-portion away from the to-be-etched layer and removing the first material layer located between the adjacent ones of the second sub-portions and covering the side of the to-be-etched layer close to the first mask layer along the direction parallel to the to-be-etched layer further comprises:
removing the second sub-portion, the first anti-reflection layer at the bottom of the first trench and the first anti-reflection layer at the bottom of the second trench, with the first anti-reflection layer on the side of the second mask layer away from the to-be-etched layer being left between the two second sub-walls in the second set of sidewalls.

In one example of the present application, the forming the first mask pattern and the second mask pattern on the side of the to-be-etched layer provided with the first mask layer through the first trench and the second trench respectively further comprises:
removing the second mask layer aligned with the first trench to form a first mask groove in the second mask layer, and removing the second mask layer aligned with the second trench to form a second mask groove in the second mask layer, wherein a length of the second mask groove is greater than a length of the first mask groove,
wherein the first mask pattern comprises the first mask groove, and the second mask pattern comprises the second mask groove.

In one example of the present application, the etching the to-be-etched layer using the first mask pattern and the second mask pattern to obtain the first patterned structure and the second patterned structure further comprises:
removing at least part of the to-be-etched layer aligned with the first mask groove to form a first groove in the to-be-etched layer, and removing at least part of the to-be-etched layer aligned with the second mask groove to form a second groove in the to-be-etched layer, wherein a length of the second groove is greater than a length of the first groove,
wherein the first patterned structure comprises the first groove, and the second patterned structure comprises the second groove.

In one example of the present application, the forming the first material layer covering the plurality of mandrel structures on the side of the first mask layer away from the to-be-etched layer further comprises:
forming a second photoresist layer on a side of the first material layer away from the first mask layer, wherein the first sub-portion is located outside coverage of the second photoresist layer, and the second sub-portion is located within the coverage of the second photoresist layer.

In one example of the present application, the removing the first sub-portion comprises:
removing the second photoresist layer to form a third set of sidewalls at two opposite sidewalls of the second sub-portion, wherein the third set of sidewalls comprises two third sub-walls at the sidewalls of the second sub-portion, the second trench is formed between two adjacent ones of the third sets of sidewalls, and the first material layer is further formed with a spacer portion at the bottom of the second trench and between adjacent ones of the third sets of sidewalls; and
removing the first sub-portion to form the first trench between the two first sub-walls in the first set of sidewalls, wherein the second trench is also located between two adjacent ones of the first sets of sidewalls.

In one example of the present application, the forming the first mask pattern and the second mask pattern on the side of the to-be-etched layer provided with the first mask layer through the first trench and the second trench respectively further comprises:
forming a first mask sidewall within the first trench and forming a second mask sidewall within the second trench, wherein between adjacent ones of the third sets of sidewalls, the second mask sidewall covers a side of the spacer portion away from the to-be-etched layer; and removing the first material layer except the spacer portion,
wherein the first mask pattern comprises the first mask sidewall, and the second mask pattern comprises the second mask sidewall.

In one example of the present application, the etching the to-be-etched layer using the first mask pattern and the second mask pattern to obtain the first patterned structure and the second patterned structure further comprises:
removing the to-be-etched layer not covered by the first mask sidewall and removing the to-be-etched layer not covered by the second mask sidewall to form a first route and a second route respectively, wherein a length of the second route is greater than a length of the first route,
wherein the first patterned structure comprises the first route, and the second patterned structure comprises the second route.

In one example of the present application, during the forming the first material layer covering the plurality of mandrel structures on the side of the first mask layer away from the to-be-etched layer,
the second sub-portion is connected with the first sub-portion in the extending direction of the mandrel structures; and the second sub-portion is connected with a side of the first sub-portion, or the second sub-portion is connected with two opposite sides of the first sub-portion.

In one example of the present application, a material of the first mask layer comprises an oxide material or a nitride material, and a material of the first material layer comprises an oxide material or a nitride material.

According to the above solution of the present application, examples of the present application further provide a semiconductor structure, wherein a first groove and a second groove are disposed in the semiconductor structure, a length of the second groove is greater than a length of the first groove, and the first groove and the second groove are formed using a first patterned structure and a second patterned structure fabricated by the patterning method.

According to the above solution of the present application, examples of the present application further provide a semiconductor structure, wherein a first route and a second route are disposed in the semiconductor structure, a length of the second route is greater than a length of the first route, and the first route and the second route are formed using a first patterned structure and a second patterned structure fabricated by the patterning method.

According to the above solution of the present application, examples of the present application further provide a memory comprising the semiconductor structure.

The present application provides a patterning method, a semiconductor structure, and a memory. By removing part of a mandrel structure after forming a first material layer, a first trench with a smaller length and a second trench with a greater length are formed, and a first mask pattern and a second mask pattern may be formed through the first trench and the second trench so as to form a first patterned structure and a second patterned structure of different lengths. Further, the applicability of the patterning method can be improved, and the process difficulty and cost of fine patterning for forming patterns of different sizes are reduced, such that the patterning method provided by the present application can meet more process requirements.

In the above-mentioned examples, the description of each example has its own emphasis, and relevant descriptions of other examples may be referred to for the parts that are detailed in certain examples.

A patterning method, a semiconductor structure and a memory provided by the examples of the present application are introduced in detail above. The principle and examples of the present application are set forth herein by applying specific individual examples. The descriptions of the examples above are only used to help understand technical solutions and core ideas of the present application. Those of ordinary skill in the art should understand that they may still modify the technical solutions as set forth in various aforementioned examples, or substitute part of the technical features with equivalents. However, these modifications or substitutions do not make the essence of the respective technical solutions depart from the scope of the technical solutions of various examples of the present application.

What is claimed is:

1. A patterning method, comprising:
forming a to-be-etched layer and a first mask layer on a side of the to-be-etched layer, wherein a plurality of mandrel structures spaced apart from each other are formed in the first mask layer, and the mandrel structure is formed with a first sub-portion and a second sub-portion on at least one side of the first sub-portion along an extending direction of the mandrel structure;
forming a first material layer covering the plurality of mandrel structures on a side of the first mask layer away from the to-be-etched layer;
removing the first material layer on a side of the first sub-portion away from the to-be-etched layer, and removing the first material layer located between adjacent ones of the first sub-portions and covering a side of the to-be-etched layer close to the first mask layer along a direction parallel to the to-be-etched layer, to form a first set of sidewalls at two opposite sidewalls of the first sub-portion, wherein the first set of sidewalls comprises two first sub-walls at the sidewalls of the first sub-portion;
removing the first sub-portion to form a first trench between the two first sub-walls in the first set of sidewalls, and a second trench between two adjacent ones of the first sets of sidewalls, wherein a length of the second trench is greater than a length of the first trench;
forming a first mask pattern and a second mask pattern on a side of the to-be-etched layer provided with the first mask layer through the first trench and the second trench respectively; and
etching the to-be-etched layer using the first mask pattern and the second mask pattern to obtain a first patterned structure and a second patterned structure, wherein a length of the second patterned structure is greater than a length of the first patterned structure.

2. The patterning method of claim 1, wherein the forming the to-be-etched layer and the first mask layer on a side of the to-be-etched layer further comprises:
forming, on a side of the to-be-etched layer, a second mask layer and a first anti-reflection layer located on a side of the second mask layer away from the to-be-etched layer; and
forming the first mask layer on a side of the first anti-reflection layer away from the second mask layer, and patterning the first mask layer to form the plurality of mandrel structures spaced apart from each other.

3. The patterning method of claim 2, wherein the forming the first material layer covering the plurality of mandrel structures on the side of the first mask layer away from the to-be-etched layer further comprises:
forming the first material layer covering the plurality of mandrel structures on a side of the first mask layer away from the first anti-reflection layer; and
forming a first photoresist layer on a side of the first material layer away from the first mask layer, wherein the first sub-portion is located outside coverage of the first photoresist layer, and the second sub-portion is located within the coverage of the first photoresist layer.

4. The patterning method of claim 3, wherein the removing the first sub-portion further comprises:
removing the first photoresist layer;
removing the first sub-portion, with the first anti-reflection layer being left at a bottom of the first trench and the first anti-reflection layer being left at a bottom of the second trench; and
removing the first material layer on a side of the second sub-portion away from the to-be-etched layer, and removing the first material layer located between adjacent ones of the second sub-portions and covering the side of the to-be-etched layer close to the first mask layer along the direction parallel to the to-be-etched layer, to form a second set of sidewalls at two opposite sidewalls of the second sub-portion, wherein the second set of sidewalls comprises two second sub-walls at the sidewalls of the second sub-portion, and the second trench is also located between adjacent ones of the second sets of sidewalls.

5. The patterning method of claim 4, wherein the removing the first material layer on the side of the second sub-portion away from the to-be-etched layer and removing the first material layer located between the adjacent ones of the second sub-portions and covering the side of the to-be-etched layer close to the first mask layer along the direction parallel to the to-be-etched layer further comprises:
removing the second sub-portion, the first anti-reflection layer at the bottom of the first trench and the first anti-reflection layer at the bottom of the second trench, with the first anti-reflection layer on the side of the second mask layer away from the to-be-etched layer being left between the two second sub-walls in the second set of sidewalls.

6. The patterning method of claim 5, wherein the forming the first mask pattern and the second mask pattern on the side of the to-be-etched layer provided with the first mask layer through the first trench and the second trench respectively further comprises:
removing the second mask layer aligned with the first trench to form a first mask groove in the second mask layer, and removing the second mask layer aligned with the second trench to form a second mask groove in the second mask layer, wherein a length of the second mask groove is greater than a length of the first mask groove,
wherein the first mask pattern comprises the first mask groove, and the second mask pattern comprises the second mask groove.

7. The patterning method of claim 6, wherein the etching the to-be-etched layer using the first mask pattern and the second mask pattern to obtain the first patterned structure and the second patterned structure further comprises:
removing at least part of the to-be-etched layer aligned with the first mask groove to form a first groove in the to-be-etched layer, and removing at least part of the to-be-etched layer aligned with the second mask groove to form a second groove in the to-be-etched layer, wherein a length of the second groove is greater than a length of the first groove,
wherein the first patterned structure comprises the first groove, and the second patterned structure comprises the second groove.

8. The patterning method of claim 1, wherein the forming the first material layer covering the plurality of mandrel structures on the side of the first mask layer away from the to-be-etched layer further comprises:
forming a second photoresist layer on a side of the first material layer away from the first mask layer, wherein the first sub-portion is located outside coverage of the second photoresist layer, and the second sub-portion is located within the coverage of the second photoresist layer.

9. The patterning method of claim 8, wherein the removing the first sub-portion comprises:
removing the second photoresist layer to form a third set of sidewalls at two opposite sidewalls of the second sub-portion, wherein the third set of sidewalls comprises two third sub-walls at the sidewalls of the second sub-portion, the second trench is formed between two adjacent ones of the third sets of sidewalls, and the first material layer is further formed with a spacer portion at a bottom of the second trench and between adjacent ones of the third sets of sidewalls; and
removing the first sub-portion to form the first trench between the two first sub-walls in the first set of sidewalls, wherein the second trench is also located between two adjacent ones of the first sets of sidewalls.

10. The patterning method of claim 9, wherein the forming the first mask pattern and the second mask pattern on the side of the to-be-etched layer provided with the first mask layer through the first trench and the second trench respectively further comprises:
forming a first mask sidewall within the first trench and forming a second mask sidewall within the second trench, wherein between adjacent ones of the third sets of sidewalls, the second mask sidewall covers a side of the spacer portion away from the to-be-etched layer; and
removing the first material layer except the spacer portion,
wherein the first mask pattern comprises the first mask sidewall, and the second mask pattern comprises the second mask sidewall.

11. The patterning method of claim 10, wherein the etching the to-be-etched layer using the first mask pattern and the second mask pattern to obtain the first patterned structure and the second patterned structure further comprises:
removing the to-be-etched layer not covered by the first mask sidewall and removing the to-be-etched layer not covered by the second mask sidewall to form a first route and a second route respectively, wherein a length of the second route is greater than a length of the first route,
wherein the first patterned structure comprises the first route, and the second patterned structure comprises the second route.

12. The patterning method of claim 1, wherein during the forming the first material layer covering the plurality of mandrel structures on the side of the first mask layer away from the to-be-etched layer,
the second sub-portion is connected with the first sub-portion in the extending direction of the mandrel structures; and
the second sub-portion is connected with a side of the first sub-portion, or the second sub-portion is connected with two opposite sides of the first sub-portion.

13. The patterning method of claim 1, wherein a material of the first mask layer comprises an oxide material or a nitride material, and a material of the first material layer comprises an oxide material or a nitride material.

14. A semiconductor structure, wherein a first groove and a second groove are disposed in the semiconductor structure, a length of the second groove is greater than a length of the first groove, and the first groove and the second groove are formed using a first patterned structure and a second patterned structure fabricated by a patterning method comprising:
forming a to-be-etched layer and a first mask layer on a side of the to-be-etched layer, wherein a plurality of mandrel structures spaced apart from each other are formed in the first mask layer, and the mandrel structure is formed with a first sub-portion and a second sub-portion on at least one side of the first sub-portion along an extending direction of the mandrel structure;
forming a first material layer covering the plurality of mandrel structures on a side of the first mask layer away from the to-be-etched layer;
removing the first material layer on a side of the first sub-portion away from the to-be-etched layer, and removing the first material layer located between adjacent ones of the first sub-portions and covering a side of the to-be-etched layer close to the first mask layer along a direction parallel to the to-be-etched layer, to form a first set of sidewalls at two opposite sidewalls of the first sub-portion, wherein the first set of sidewalls comprises two first sub-walls at the sidewalls of the first sub-portion;
removing the first sub-portion to form a first trench between the two first sub-walls in the first set of sidewalls, and a second trench between two adjacent ones of the first sets of sidewalls, wherein a length of the second trench is greater than a length of the first trench;
forming a first mask pattern and a second mask pattern on a side of the to-be-etched layer provided with the first mask layer through the first trench and the second trench respectively; and
etching the to-be-etched layer using the first mask pattern and the second mask pattern to obtain a first patterned structure and a second patterned structure, wherein a length of the second patterned structure is greater than a length of the first patterned structure.

15. A semiconductor structure, wherein a first route and a second route are disposed in the semiconductor structure, a length of the second route is greater than a length of the first route, and the first route and the second route are formed using a first patterned structure and a second patterned structure fabricated by a patterning method comprising:
forming a to-be-etched layer and a first mask layer on a side of the to-be-etched layer, wherein a plurality of mandrel structures spaced apart from each other are formed in the first mask layer, and the mandrel structure is formed with a first sub-portion and a second sub-portion on at least one side of the first sub-portion along an extending direction of the mandrel structure;
forming a first material layer covering the plurality of mandrel structures on a side of the first mask layer away from the to-be-etched layer;
removing the first material layer on a side of the first sub-portion away from the to-be-etched layer, and removing the first material layer located between adjacent ones of the first sub-portions and covering a side of the to-be-etched layer close to the first mask layer along a direction parallel to the to-be-etched layer, to form a first set of sidewalls at two opposite sidewalls of the first sub-portion, wherein the first set of sidewalls comprises two first sub-walls at the sidewalls of the first sub-portion;
removing the first sub-portion to form a first trench between the two first sub-walls in the first set of sidewalls, and a second trench between two adjacent ones of the first sets of sidewalls, wherein a length of the second trench is greater than a length of the first trench;
forming a first mask pattern and a second mask pattern on a side of the to-be-etched layer provided with the first mask layer through the first trench and the second trench respectively; and
etching the to-be-etched layer using the first mask pattern and the second mask pattern to obtain a first patterned structure and a second patterned structure, wherein a length of the second patterned structure is greater than a length of the first patterned structure.
